(19) United States
(12) Patent Application Publication
(10) Pub. No.: US 2013/0208018 A1
(43) Pub. Date: Aug. 15, 2013

(54) FLAT PANEL DISPLAY DEVICE AND A METHOD OF DRIVING THE SAME

(71) Applicants: Min-Tak Lee, Yongin-city (KR); Young-Nam Yun, Yongin-city (KR); Hyun-Koo Lee, Yongin-city (KR)

(72) Inventors: Min-Tak Lee, Yongin-city (KR); Young-Nam Yun, Yongin-city (KR); Hyun-Koo Lee, Yongin-city (KR)

(21) Appl. No.: 13/535,307

(22) Filed: Jun. 27, 2012

(30) Foreign Application Priority Data
Feb. 14, 2012 (KR) 10-2012-0014828

(51) Int. Cl. G09G 3/32; G09G 5/10

(52) U.S. Cl. 345/690; 345/77

(57) ABSTRACT

A flat panel display device includes a display panel for displaying an image in a first direction and for displaying the image in a second direction, the display panel including an emissive diode, a first surface, and a second surface substantially parallel to and opposite the first surface, a light-irradiating unit facing the first surface for irradiating light overlapping the image displayed in the second direction, and a control unit for operating the light-irradiating unit, wherein the first direction is substantially perpendicular to the second surface and the second direction forms an inclination angle, with the second surface.

### CROSS-REFERENCE TO RELATED PATENT APPLICATION

This application claims priority to and the benefit of Korean Patent Application No. 10-2012-0014828, filed on Feb. 14, 2012, in the Korean Intellectual Property Office, the disclosure of which is incorporated herein in its entirety by reference.

### BACKGROUND

1. Field

Embodiments of the present invention relate to a flat panel display device and a method of driving the same.

2. Description of the Related Art

Of flat panel display devices, organic light-emitting display devices, which include emissive diodes, and have wider viewing angles than liquid crystal display devices. This is because an organic light-emitting device, which is an emissive diode, scatters light emitted from a light-emitting layer.

However, in the case of a wide viewing angle, an image displayed on a screen may be viewed by persons other than a user viewing the image in front of the screen, and thus, the security, or privacy, of information corresponding to the image may be reduced.

However, the user does not always desire a narrow viewing angle, and thus, artificially reducing the wide viewing angle to a small viewing angle may be a problem. This means that a display device having a wide viewing angle, which is an advantage of the display device, is degraded at a cost.

### SUMMARY

Embodiments of the present invention provide a flat panel display device having an adjustable viewing angle and a method of driving the same.

According to an aspect of embodiments of the present invention, there is provided a flat panel display device including a display panel for displaying an image in a first direction and for displaying the image in a second direction, the display panel including an emissive diode, a first surface, and a second surface substantially parallel to and opposite the first surface, a light-irradiating unit facing the first surface for irradiating light overlapping the image displayed in the second direction, and a control unit for operating the light-irradiating unit, wherein the first direction is substantially perpendicular to the second surface and the second direction forms an inclination angle with the second surface.

The light-irradiating unit may include a light-emitting device for irradiating the light, and a light guide plate for guiding the light emitted from the light-emitting device towards the first surface in the second direction, and the light guide plate may include a third surface facing the first surface, and a fourth surface opposite the third surface.

The light guide plate may further include a first pattern for refracting the light emitted from the light-emitting device onto the fourth surface in the second direction.

The first pattern may be a corrugated pattern including a plurality of ridges on the fourth surface.

A cross-section of one of the plurality of ridges may be arc-shaped.

A cross-section of one of the plurality of ridges may be triangular-shaped.

The third surface may include a second pattern for diffusing the light refracted by the first pattern.

The second pattern may include a saw tooth pattern.

The flat panel display device may further include a light absorption sheet adjacent the fourth surface.

The light-emitting device may include a first part and a second part that are adjacent opposite edges of the light guide plate.

The inclination angle may be in a range from about 0° to about 60°.

According to an aspect of embodiments of the present invention, there is provided a method of driving a flat panel display device including a display panel including an emissive diode, a first surface, and a second surface substantially parallel to and opposite the first surface, the method including displaying an image towards the second surface in a first direction that is substantially perpendicular to the second surface and in a second direction forming an inclination angle with the second surface, and irradiating light overlapping the image in the second direction.

The inclination angle may be in a range from about 0° to about 60°.

### BRIEF DESCRIPTION OF THE DRAWINGS

The above and other features of the present invention will become more apparent by describing in detail exemplary embodiments thereof with reference to the attached drawings in which:

FIG. 1 is a cross-sectional view of a flat panel display device according to an embodiment of the present invention;

FIG. 2 is a cross-sectional view of the flat panel display panel shown in FIG. 1, according to an embodiment of the present invention;

FIG. 3 is a cross-sectional view of the flat panel display panel shown in FIG. 1, according to another embodiment of the present invention;

FIG. 4 is a cross-sectional view of a pixel of the flat panel display panel of the embodiment shown in FIG. 2, according to an embodiment of the present invention;

FIG. 5 is a cross-sectional view of a light-guiding plate shown in FIG. 1, according to an embodiment of the present invention; and

FIG. 6 is a cross-sectional view of the light-guiding plate shown in FIG. 1, according to another embodiment of the present invention.

### DETAILED DESCRIPTION

Embodiments of the present invention will be described more fully with reference to the accompanying drawings, in which exemplary embodiments of the present invention are shown.

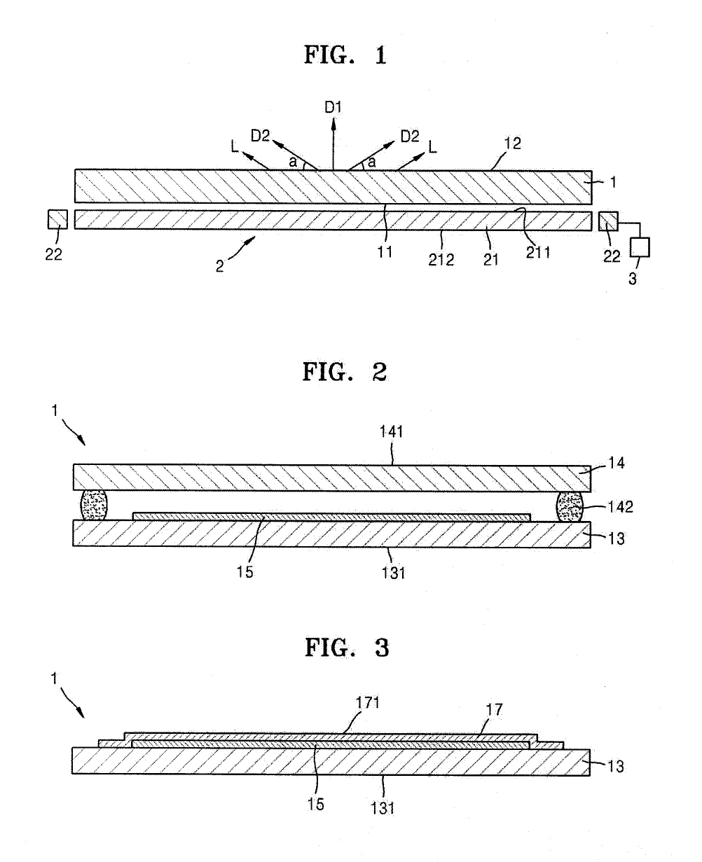

FIG. 1 is a cross-sectional view of a flat panel display device according to an embodiment of the present invention.

Referring to FIG. 1, the flat panel display device includes a flat panel display panel 1 that displays an image, a light-irradiating unit 2 that irradiates light to the flat panel display panel 1, and a control unit 3 that optionally operates the light-irradiating unit 2.

According to the present embodiment, the flat panel display panel 1 may include emissive diodes (e.g., light emitting diodes), and may be an organic light-emitting display panel.

The flat panel display panel 1 includes a first surface 11 and a second surface 12, which are parallel to each other. The first surface 11 faces the light-irradiating unit 2, and an image is displayed on the second surface 12.

The flat panel display panel 1, such as an organic light-emitting display panel, has wide viewing angles. That is, an image displayed from the flat panel display panel 1 may be seen from a direction perpendicular to the second surface 12 as well as from slanted, or angled, directions. Accordingly, the image includes a first image D1 projected in a first direction that is perpendicular to the second surface 12, and a second image D2 projected in a second direction that forms an inclination angle “a” with respect to the second surface 12, and the first image D1 and the second image D2 are concurrently, or simultaneously, produced.

FIG. 2 is a cross-sectional view of the flat panel display panel 1 shown in FIG. 1, according to an embodiment of the present invention. An organic light-emitting unit 15 is formed on a first substrate 13, and a second substrate 14 is positioned facing the first substrate 13. The first substrate 13 and the second substrate 14 are combined by a sealant 142 located outside the organic light-emitting unit 15 to seal a space between the first substrate 13 and the second substrate 14. The space may be filled with a moisture absorbent or a filler. In this structure, when seen as corresponding to the view of the flat panel display device shown in FIG. 1, a lower surface 131 of the first substrate 13 may be the first surface 11 shown in FIG. 1, and an upper surface 141 of the second substrate 14 may be the second surface 12 shown in FIG. 1, In the present embodiment, the flat panel display panel 1 is a top emission-type organic light-emitting display panel. According to other embodiments of the present invention, and when seen as corresponding to the view of the flat panel display device shown in FIG. 1, the lower surface 131 of the first substrate 13 may be the second surface 12, and the upper surface 141 of the second substrate 14 may be the first surface 11. In such embodiments, the flat panel display panel 1 may be a bottom emission-type organic light-emitting display panel.

FIG. 3 is a cross-sectional view of the flat panel display panel 1 shown in FIG. 1, according to another embodiment of the present invention. An organic light-emitting unit 15 is formed on a first substrate 13, and a sealing thin-film 17 is formed on the first substrate 13 to cover and protect the organic light-emitting unit 15 from external air. The sealing thin-film 17 may have a structure in which a film formed of an inorganic material such as, for example, aluminum oxide, silicon oxide, or silicon nitride, and a film formed of an organic material such as, for example, epoxy or polyimide are alternately formed. However, the sealing thin-film 17 is not limited thereto, and the sealing thin-film 17 may have any structure as long as it is a transparent thin-film sealing structure. In this structure, when seen as corresponding to the view of the flat panel display device shown in FIG. 1, the lower surface 131 of the first substrate 13 may be the first surface 11 of FIG. 1, and an upper surface 171 of the sealing thin-film 17 may be the second surface 12 of FIG. 1. In this case, the flat panel display panel 1 may be a top emission-type organic light-emitting display panel. Also, according to other embodiments of the present invention, when seen as corresponding to the view of the flat panel display device shown in FIG. 1, the lower surface 131 of the first substrate 13 may be the second surface 12, and the upper surface 171 of the sealing thin-film 17 may be the first surface 11. According to such embodiments, the flat panel display panel 1 may be a bottom emission-type organic light-emitting display panel.

Although not shown, according to another embodiment of the present invention, as a sealing structure for sealing the organic light-emitting unit 15, the second substrate 14 shown in FIG. 2 may further be included after forming the sealing thin-film 17 of FIG. 3.

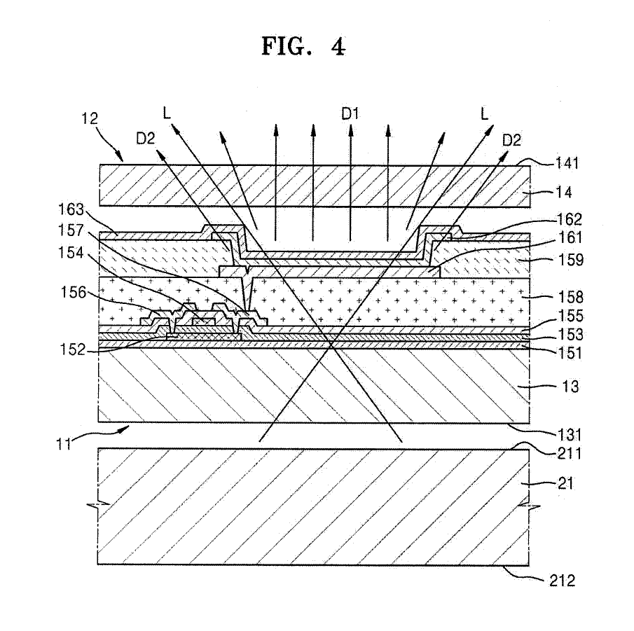

The organic light-emitting unit 15, as shown in FIG. 4, realizes an image by including a plurality of pixels that each include a thin-film transistor and an organic light-emitting device (e.g., an organic light emitting diode).

FIG. 4 is a cross-sectional view of a pixel of the flat panel display panel 1 shown in FIG. 2, according to an embodiment of the present invention. First, a buffer film 151 is formed on the first substrate 13, and a pixel circuit unit including a thin-film transistor is formed on the buffer film 151.

A semiconductor active layer 152 is formed on the buffer film 151.

The buffer film 151 may be formed of a transparent material and may reduce or prevent impurity elements from penetrating into the pixel, and may planarize the surface thereof. The buffer film 151 may be formed of various materials that perform the above functions, for example, an inorganic material, such as silicon oxide, silicon nitride, silicon oxynitride, aluminum oxide, aluminum nitride, titanium oxide, or titanium nitride, or an organic material, such as, for example, polyimide, polyester, or acryl, or a stack of these materials. The buffer film 151 is not an essential element, and thus, need not be formed if the buffer film is undesired.

The semiconductor active layer 152 may be formed of polycrystalline silicon. However, the semiconductor active layer 152 is not limited thereto, and the semiconductor active layer 152 may be formed of an oxide semiconductor, for example, a (In₂O₃)a(Ga₂O₃)b(ZnO)c (G-I—Z—O) layer (here, a, b, and c are real numbers that respectively satisfy conditions of a≧0, b≧0, and c>0). When the semiconductor active layer 152 is formed of an oxide semiconductor, optical transmittance may further be increased, and accordingly, the overall external optical transmittance of the organic light-emitting unit 15 may be increased.

A gate insulating film 153 is formed on the buffer film 151 by using a transparent insulating material to cover the semiconductor active layer 152, and a gate electrode 154 is formed on the gate insulating film 153.

An interlayer insulating layer 155 is formed on the gate insulating film 153 by using a transparent insulating material to cover the gate electrode 154. A source electrode 156 and a drain electrode 157 are formed on the interlayer insulating layer 155, and are connected to the semiconductor active layer 152 through contact holes.

The structure of the thin-film transistor according to the present invention is not limited to the present embodiment, and various types of thin-film transistor structures may be applied.

A passivation film 158 is formed to cover the pixel circuit unit that includes the thin-film transistor described above. The passivation film 158 may be a single layer or a multi-layered insulating layer, an upper surface of which is planarized. The passivation film 158 may be formed of a transparent inorganic and/or organic insulating material. The passivation film 158 may be formed across all the pixels.

As shown in FIG. 4, a first electrode 161 of the organic light-emitting device, which is electrically connected to the thin-film transistor, is formed on the passivation film 158. The first electrode 161 is formed as a separate and independent island-type electrode for each pixel.

A pixel-defining film 159 is formed on the passivation film 158 by using an organic and/or inorganic insulating material.

The pixel-defining film 159 covers edges of the first electrode 161 and exposes a central region of the first electrode 161.

An organic film 162 and a second electrode 163 are sequentially stacked on the first electrode 161. The second electrode 163 covers the organic film 162 and the pixel-defining film 159, and is electrically connected across all the pixels.

The organic film 162 may be, for example, a low molecule organic film or a polymer organic film. If the organic film 162 is a low molecule organic film, the organic film 162 may include a hole injection layer (HIL), a hole transport layer (HTL), an emission layer (EML), an electron transport layer (ETL), or an electron injection layer (EIL) stacked in a single layer structure or a composite layer structure, and may be formed of various organic materials, for example, copper phthalocyanine (CuPc), N,N′-di(naphthalene-1-yl)-N,N′-diphenyl-benzidine (NPB), or tris-8-hydroxyquinoline aluminum (Alq3). The low molecule organic film of the present embodiment may be formed by using a vacuum evaporation method. The HIL, the HTL, the ETL, and the EIL are common electrodes, and may be commonly formed in red, green, and blue pixels.

The first electrode 161 may function as an anode electrode, and the second electrode 163 may function as a cathode electrode. Of course, polarities of the first electrode 161 and the second electrode 163 may be reversed.

According to the present embodiment, the first electrode 161 may be a transparent electrode, and the second electrode 163 may be a reflective electrode. The first electrode 161 may be formed of a material having a high work function, such as a material selected from the group consisting of ITO, IZO, ZnO, and In₂O₃. The second electrode 163 may be formed of a metal having a low work function, such as a metal selected from the group consisting of Ag, Mg, Al, Pt, Pd, Au, Ni, Nd, Ir, Cr, Li, and Ca. Accordingly, the organic light-emitting device is a bottom emission-type device in which an image is displayed in a direction towards the first electrode 161.

However, the present invention is not limited thereto, that is, the second electrode 163, may also be formed as a transparent electrode.

The passivation film 158, the gate insulating film 153, the interlayer insulating layer 155, and the pixel-defining film 159 may be formed of a transparent insulating film.

The second substrate 14 may be disposed on the second electrode 163. An additional passivation film (not shown) may further be additionally formed on the second electrode 163.

In the present embodiment, the light-irradiating unit 2 is optionally operated by the control of the control unit 3, and irradiates light L towards the first surface 11 of the flat panel display panel 1 (refer to FIG. 1). At this point, the light L emitted from the light-irradiating unit 2 overlaps with the second image D2 realized in the second direction. Accordingly, the user may not view the second image D2 due to the light L of the light-irradiating unit 2. This operation may be controlled by the control unit 3 when it is necessary or desired to reduce the viewing angle due to security reasons.

The inclination angle “a” (see FIG. 1) corresponding to the second direction may be in a range from about 0° to about 60°. Accordingly, when the light-irradiating unit 2 is operated by the control of the control unit 3, the user may have difficulty viewing an image from the second surface 12 in a viewing angle between 0° and 60°.

The light-irradiating unit 2 includes a light guide plate 21 and light-emitting devices 22.

The light-emitting devices 22 are a light source of the light L, and may be a light-emitting diode (LED). The light-emitting devices 22 are disposed on edges of the light guide plate 21, and, as shown in FIG. 1, may be disposed on both, or opposite, sides of the light guide plate 21. At this point, the light-emitting devices 22 may be disposed on both (e.g., opposite) edges of the light guide plate 21 in directions corresponding to limiting the viewing angle.

The light guide plate 21 guides light emitted from the light-emitting device 22 in a direction towards the flat panel display panel 1. The light guide plate 21 may be formed of a transparent plate so the light may transmit therethrough, and includes a third surface 211 and a fourth surface 212 opposite each other.

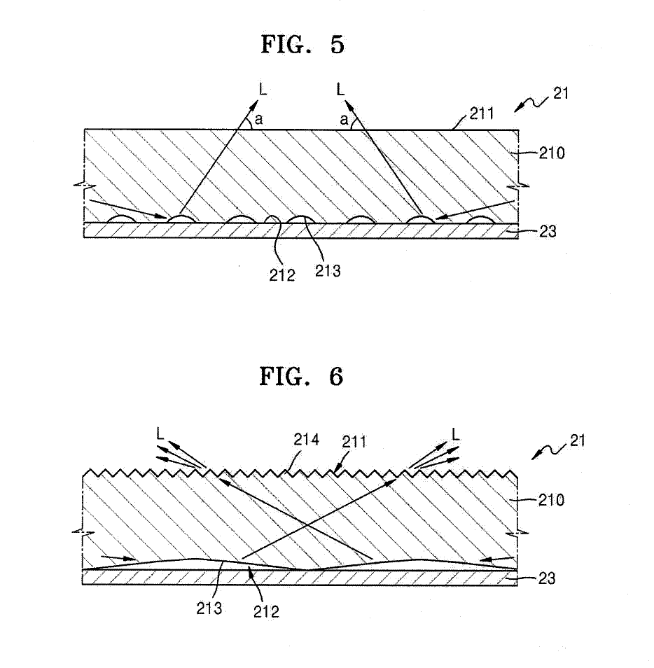

FIG. 5 is a cross-sectional view of the light guide plate 21 shown in FIG. 1, according to an embodiment of the present invention. The light guide plate 21 includes a plate 210 formed of a transparent material. The third surface 211 and the fourth surface 212 are both surfaces of the plate 210. A first pattern 213 that refracts light L emitted from the light-emitting device 22 in the second direction is formed on the fourth surface 212. As shown in FIG. 5, the light L that is refracted by the first pattern 213 leaves the light guide plate 21 in the second direction that forms an inclination angle “a” with respect to the fourth surface 212, which is parallel to the first surface 11 and the second surface 12.

As shown in FIG. 5, the first pattern 213 may be formed as a plurality of grooves having a corrugated pattern, which is formed on the fourth surface 212 of the plate 210. Although not shown, a cross-section of ridges of the corrugated pattern may have a circular or oval arc. The corrugated grooves may be formed as long linear-type corrugated grooves along a direction perpendicular to the direction of limiting the viewing angle. However, the present invention is not limited thereto, and the first pattern 213 may be formed in a dot pattern. Although not shown, the first pattern 213 may be included as a printed protrusion unit on the fourth surface 212.

A light absorption sheet 23 may be formed adjacent and/or facing the fourth surface 212. The light absorption sheet 23 may increase a front visibility of the flat panel display panel 1. That is, the light absorption sheet 23 increases visibility from the front of the flat panel display panel 1 by blocking light is reflected after exiting the light guide plate 21 and enters into the flat panel display panel 1.

FIG. 6 is a cross-sectional view of the light-guiding plate 21 shown in FIG. 1, according to another embodiment of the present invention. Referring to FIG. 6, a second pattern 214 that diffuses the light L may further be formed on the third surface 211. The second pattern 214 may be a corrugated pattern having ridges with triangular cross-sections (e.g., the second pattern 214 may be a saw tooth pattern) that are regularly or irregularly repeated. The second pattern 214 may be a pattern that may further diffuse the light L incident to the third surface 211 towards the inclination directions, and may be a prism sheet pattern, which may be designed by controlling an angle or magnitude of an apex angle of a prism. The diffusion directions of light may be, as shown in FIG. 1, both inclination directions in which the light-emitting devices 22 are disposed. The second pattern 214 might not necessarily be formed directly on the third surface 211, and may be attached to the third surface 211 after forming the second pattern 214 on a separate sheet.

As described above, in a normal operation, the user may use the wide viewing angle of the flat panel display panel 1. However, when it is necessary or desirable to reduce the viewing angle from a particular point, the viewing angle may be simply reduced.

While the present invention has been particularly shown and described with reference to exemplary embodiments thereof, it will be understood by those of ordinary skill in the art that various changes in form and details may be made therein without departing from the spirit and scope of the present invention as defined by the following claims, and their equivalents.

What is claimed is:

1. A flat panel display device comprising:
a display panel for displaying an image in a first direction and for displaying the image in a second direction, the display panel comprising:
an emissive diode;
a first surface; and
a second surface substantially parallel to and opposite the first surface,
a light-irradiating unit facing the first surface for irradiating light overlapping the image displayed in the second direction; and
a control unit for operating the light-irradiating unit,
wherein the first direction is substantially perpendicular to the second surface and the second direction forms an inclination angle with the second surface.

2. The flat panel display device of claim 1, wherein the light-irradiating unit comprises:
a light-emitting device for irradiating the light; and
a light guide plate for guiding the light emitted from the light-emitting device towards the first surface in the second direction, wherein the light guide plate comprises a third surface facing the first surface, and a fourth surface opposite the third surface.

3. The flat panel display device of claim 2, wherein the light guide plate further comprises a first pattern for refracting the light emitted from the light-emitting device onto the fourth surface in the second direction.

4. The flat panel display device of claim 3, wherein the first pattern is a corrugated pattern comprising a plurality of ridges on the fourth surface.

5. The flat panel display device of claim 4, wherein a cross-section of one of the plurality of ridges is arc-shaped.

6. The flat panel display device of claim 4, wherein a cross-section of one of the plurality of ridges is triangular-shaped.

7. The flat panel display device of claim 3, wherein the third surface comprises a second pattern for diffusing the light refracted by the first pattern.

8. The flat panel display device of claim 7, wherein the second pattern comprises a saw tooth pattern.

9. The flat panel display device of claim 2, further comprising a light absorption sheet adjacent the fourth surface.

10. The flat panel display device of claim 2, wherein the light-emitting device comprises a first part and a second part that are adjacent opposite edges of the light guide plate.

11. The flat panel display device of claim 1, wherein the inclination angle is in a range from about 0° to about 60°.

12. A method of driving a flat panel display device comprising a display panel comprising an emissive diode, a first surface, and a second surface substantially parallel to and opposite the first surface, the method comprising:
displaying an image towards the second surface in a first direction that is substantially perpendicular to the second surface and in a second direction forming an inclination angle with the second surface; and
irradiating light overlapping the image in the second direction.

13. The method of claim 12, wherein the inclination angle is in a range from about 0° to about 60°.
